(19) United States
(12) Patent Application Publication
(10) Pub. No.: US 2013/0247981 A1
(43) Pub. Date: Sep. 26, 2013

(54) SOLAR CELL FABRICATION USING A PRE-DOPING DIELECTRIC LAYER

(71) Applicants: VIJAY YELUNDUR, CANTON, GA (US); ATUL GUPTA, BEVERLY, MA (US); JASEN MOFFITT, JOHNS CREEK, GA (US)

(72) Inventors: VIJAY YELUNDUR, CANTON, GA (US); ATUL GUPTA, BEVERLY, MA (US); JASEN MOFFITT, JOHNS CREEK, GA (US)

(73) Assignee: SUNIVA, INC., NORCROSS, GA (US)

(21) Appl. No.: 13/426,123

(22) Filed: Mar. 21, 2012

(51) Int. Cl. H01L 31/0232; H01L 31/02

(52) U.S. Cl. 136/259; 136/252; 438/69; 257/E31.127

(57) ABSTRACT

Solar cells, solar modules, and methods for their manufacture are disclosed. An example method may comprise forming a dielectric layer on at least one or more edges of a substrate, and then introducing dopant to at least one surface of the substrate. The substrate may be subjected to a heating process to at least drive the dopant to a predefined depth, thereby forming at least one of an emitter layer and a surface field layer. In the example method, the dielectric layer may not be removed during a subsequent manufacturing process. Associated solar cells and solar modules are also provided.

### TECHNOLOGICAL FIELD

The present invention is generally directed to methods for forming a solar cell using a dielectric layer on a silicon wafer prior to a doping step, and the solar cells that result from such a process.

### BACKGROUND

In basic design, a solar cell is composed of a material such as a semiconductor substrate that absorbs energy from photons to generate electricity through the photovoltaic effect. When photons of light penetrate into the substrate, the energy is absorbed and an electron previously in a bound state is freed. The newly freed electron and the emptied state, which may be referred to as a hole, are referred to as charge carriers.

The substrate is generally doped with p-type and n-type impurities to create an electric field inside the solar cell, called a p-n junction. In order to use the free charge carriers to generate electricity, the electrons and holes must not recombine before they can be separated by the electrical field at the p-n junction. The charge carriers that do not recombine can then be used to draw power through an external load. It is desirable to avoid parallel conductive paths (i.e., shunts) internal to the solar cell that can allow the separated charge carriers to recombine within the solar cell under illumination. Such recombination may lower the useful power that can be drawn from the solar cell through the external loads.

FIG. 1 illustrates an example method for forming a solar cell according to conventional processes. At operation 100, the process may begin with the cleaning and texturing of a substrate. At operation 105, dopant is introduced to a surface of the substrate. At operation 110, the substrate is subjected to a dopant drive-in process. At operation 115, an antireflection layer is formed over the front surface of the substrate. At operations 120, 125, front and back contacts and connections may be applied. At operation 130, the front and back contacts and connections may be co-fired.

During the fabrication of a solar cell such as via the conventional process illustrated in FIG. 1, which may comprise doping of the front and/or back surfaces of the solar cell, it is not uncommon for the edges on the sides of the solar cell to also become doped. For example the front of the solar cell having a p-type substrate may be doped to create an n-type region that may be referred to as the emitter. In order to reduce free carrier recombination on the back side of the solar cell, it may be desirable to form a more heavily doped p-type region to help boost the cell performance by creating a relatively small barrier for the electrons through an electric field due to the difference in doping levels near the back surface of the solar cell. The creation of the heavily doped p-type region may be accomplished through the formation of an alloyed region using aluminum paste during a firing process to make metal contacts to the oppositely doped regions. The shunting pathways may exist in solar cells where regions with heavy doping of opposing polarities are joined together, thus allowing the previously separated free carriers to tunnel across to the other electrode through the substrate itself thereby bypassing the external load. Such shunting pathways may occur on any surface but may be more commonly found around the edges of the substrate. It is also possible for particles, such as aluminum, to contaminate the edges of the solar cell during various stages of the process, for example, formation of the contacts. When the edges of a solar cell are doped in this way, a conductive path may be formed between an aluminum particle on the edge of the wafer and the electrical contacts on the front side of the solar cell. The aluminum particle may alloy with silicon during the contact firing process and form a low resistance contact to the base of the solar cell. In this way a conductive path may be formed between the base of the solar cell and the front or back electrical contact that may shunt the p-n junction.

A common method for eliminating this conductive path to the shunting particle involves either physically cutting or chemically etching a trench through the doped layer. This step, known as junction isolation, often reduces the active area and power output of the solar cell by an amount proportional to the distance between the trench and the edge of the solar cell. Furthermore, junction isolation adds another step to the process of solar cell manufacturing that may increase the cost while decreasing throughput.

Therefore, there is a need in the art for developing a method for producing solar cells that overcome the above-mentioned and other disadvantages and deficiencies of previous technologies.

### BRIEF SUMMARY OF SOME EXAMPLES OF THE INVENTION

Various embodiments of a solar cell having a dielectric layer formed prior to a doping step and methods for its manufacture are herein disclosed. These embodiments of the invention overcome one or more of the above-described disadvantages associated with previous technologies. Embodiments of the invention provide several advantages for production of solar cells.

In an example embodiment, a method for manufacturing a solar cell is provided. The method may comprise forming a dielectric layer on at least one or more edges of a substrate, and then introducing dopant to at least one surface of the substrate. The substrate may be subjected to a heating process to at least drive the dopant to a predefined depth, thereby forming at least one of an emitter layer and a surface field layer. In the example method, the dielectric layer may not be removed during a subsequent manufacturing process.

In another example embodiment, a solar cell is provided. The solar cell may be manufactured by the steps of forming a dielectric layer on at least one or more edges of a substrate, and then introducing dopant to at least one surface of the substrate. The substrate may be subjected to a heating process to at least drive the dopant to a predefined depth, thereby forming at least one of an emitter layer and a surface field layer. In the example solar cell, the dielectric layer may not be removed during a subsequent manufacturing process.

In another example embodiment, a solar module is provided. The solar module may comprise one or more solar cells manufactured by the steps of forming a dielectric layer on at least one or more edges of a substrate, and then introducing dopant to at least one surface of the substrate. The substrate may be subjected to a heating process to at least drive the dopant to a predefined depth, thereby forming at least one of an emitter layer and a surface field layer. In the example solar module, the dielectric layer of the one or more solar cells may not be removed during a subsequent manufacturing process.

### BRIEF DESCRIPTION OF THE DRAWING(S)

The foregoing summary as well as the following detailed description of the various example embodiments of the present invention will be better understood when read in conjunction with the appended drawings. It is understood that the invention is not limited to the precise arrangements and instrumentalities shown and that the drawings are not necessarily drawn to scale. In the drawings:

FIG. 1 illustrates a flowchart of a conventional method for manufacturing a solar cell;

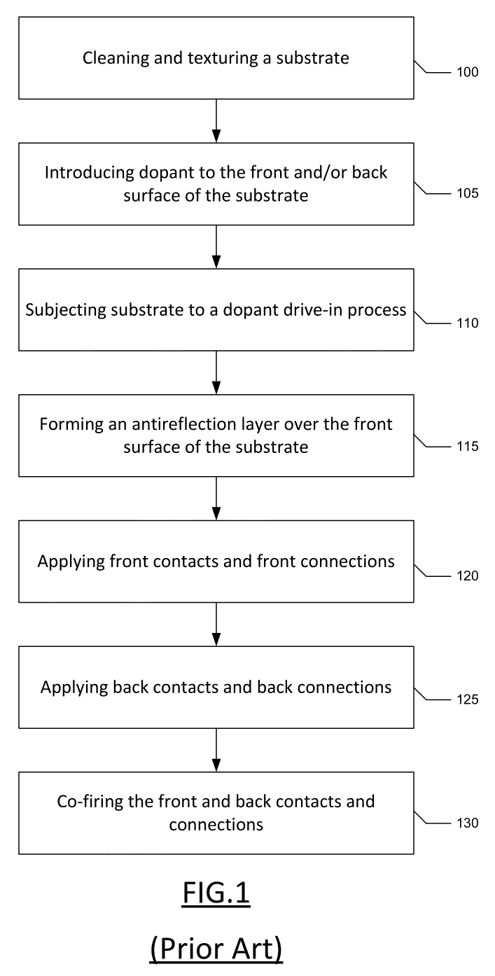

FIG. 2 illustrates a flowchart of a method for manufacturing a solar cell comprising a pre-doping dielectric layer according to an example embodiment of the present invention;

FIG. 3 illustrates a flowchart of a method for manufacturing a solar cell comprising a pre-doping dielectric layer according to an example embodiment of the present invention;

FIG. 4 illustrates a flowchart of a method for manufacturing a solar cell comprising a pre-doping dielectric layer according to an example embodiment of the present invention;

FIG. 5 illustrates a cross-sectional view of a solar cell that may benefit from various embodiments of the present invention; and

FIG. 6 illustrates a cross-sectional view of a bifacial solar cell that may benefit from various embodiments of the present invention.

### DETAILED DESCRIPTION

Some embodiments of the present invention will now be described more fully hereinafter with reference to the accompanying drawings, in which some, but not all embodiments of the invention are shown. Those skilled in this art will understand that the invention may be embodied in many different forms and should not be construed as limited to the embodiments set forth herein; rather, these embodiments are provided so that this disclosure will satisfy applicable legal requirements. Like reference numerals refer to like elements throughout.

Solar cells with a doped emitter, front surface field layer, and/or back surface field layer commonly follow a process sequence for solar cell fabrication that does not include formation of a dielectric layer prior to doping. In a common sequence, wafers are processed from texturing directly to a doping step and drive-in step where the edges of the wafers may become doped with dopant, which may lead to undesirably high shunt resistances and reverse bias leakage currents.

Various embodiments of the present invention eliminate or greatly reduce the doping of the edge of the wafers, which reduces the likelihood of shunting, by providing for a pre-doping formation of a dielectric layer at least along the sides or edges of the substrate. The formation of a dielectric layer may be achieved, in certain embodiments, using manufacturing steps such as thermal oxidation that have a low cost for consumables and low wafer breakage. By blocking or preventing the doping of the edges of the wafer, various advantageous embodiments increase the shunt resistance of the solar cell and reduce the reverse bias leakage current without otherwise detrimentally affecting the performance of the solar cell (e.g., by reducing fill factor or efficiency).

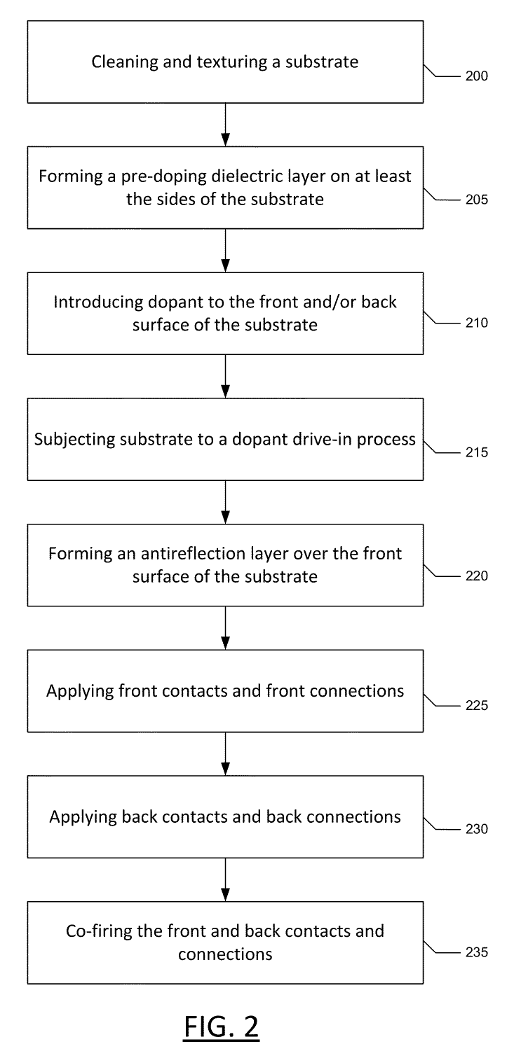

FIG. 2 illustrates a flowchart depicting an example method for forming a dielectric layer prior to a doping step according to an example embodiment of the present invention.

Referring to FIG. 2 at operation 200 a substrate may be prepared for processing. The substrate may be ordered from suppliers with a specified amount of p-type or n-type conductivity. In other embodiments, the substrate may be doped to achieve a certain p-type or n-type level. The substrate may then be cleaned to prepare it for processing. The cleaning may be accomplished by immersion of the substrate in a bath of potassium hydroxide (KOH) having, for example, about a 1-10% concentration, to etch away saw damage on the surfaces of the substrate. According to some example embodiments, etching may be conducted at a temperature from about 60 to 90 degrees Celsius.

The substrate may further be textured at operation 200. For example, the substrate may be textured by anisotropically etching it by immersion in a bath of potassium hydroxide and isopropyl alcohol (KOH-IPA). According to some example embodiments, the potassium hydroxide concentration may be about a 1-10% concentration, and the isopropyl alcohol may be about a 2-20% concentration. The temperature of the KOH-IPA bath may be about 65 to 90 degrees Celsius. The KOH-IPA etches the surfaces of the substrate to form pyramidal structures with faces at the crystallographic orientation. The resulting pyramidal structures may help to reduce reflectivity at the front surface and to trap light within the substrate where it can be absorbed for conversion to electric energy. Other chemical mixtures (e.g. a high boiling alcohol and KOH or acid based mixtures) or other texturing techniques such as plasma based etches or laser based processes may be used for providing a textured surface for the solar cells in other embodiments.

At operation 205, a dielectric layer may be formed on all or a portion of the surfaces of the substrate. In this regard, the dielectric layer may be formed by thermal oxidation (e.g., in a quartz tube furnace), wet chemical oxidation, chemical vapor deposition, physical vapor deposition, or any other suitable means. The dielectric layer may comprise a dielectric material such as silicon dioxide (SiO₂) for a silicon substrate, or an oxide of another semiconductor type, depending upon the composition of the substrate. The dielectric layer may be formed at a thickness sufficiently thick to serve as an effective diffusion barrier but sufficiently thin to avoid significantly increasing the emitter sheet resistance and/or fill factor of the solar cell. In this regard, the dielectric layer may be formed at a thickness in a range from 0.5 to 150 nanometers, for example between two to five nanometers.

In some embodiments, the dielectric layer formed in operation 205 may cover the entire surface of the substrate including the edges of the substrate. In other embodiments, the dielectric layer may be formed only on the edges of the substrate, that is, along the sides of the substrate. For example, the front and/or back surfaces of the substrate may be covered by a mask while the dielectric layer is formed on the edges. In another example the dielectric may be formed with the substrates placed in a coinstacked manner and thus acting themselves as masks for the adjacent substrates. According to various embodiments, the dielectric layer formed in operation 205 may remain as a component of the solar cell. For example, in some instances, no portion of the dielectric layer formed during operation 205 may be removed from the solar cell during subsequent operations (i.e., a subsequent manufacturing process). In other embodiments, a portion of the dielectric layer may be removed in subsequent operations (i.e., a subsequent manufacturing process). In yet other embodiments, the entire dielectric layer may be removed during subsequent operations (i.e., a subsequent manufacturing process). In certain embodiments, not removing all or a portion of the dielectric layer may advantageously reduce the number of processing steps and thereby the cost of producing a solar cell.

At operation 210, dopant, for example dopant atoms or ions, may be introduced to the front and/or back surface of the substrate. The dopant may serve to form an emitter and/or a front or back surface field layer. The dopant may be introduced uniformly to the surfaces or in different levels for different regions (i.e., to form a selective emitter or selective surface field). According to various embodiments, the dopant may be introduced via ion implantation, liquid dopant sources (e.g., phosphorus oxychloride (POCl₃)), source wafers, screen printing, doped deposited films, and/or the like. In some embodiments, the sides of the substrate, which comprise the dielectric layer, may also be exposed to the dopant while it is introduced to the front and/or back surfaces. Various embodiments may be used for doping processes that are designed to dope one side of the substrate at a time, while the opposite side may require dopant of an opposite type. For example, a solar cell may have p-type doping on one face and n-type doping on the opposite face of the substrate. In these embodiments, heavy doping may be desired on the opposite faces but not at the locations where the two heavily doped regions intersect each other.

At operation 215, the substrate may be subjected to a dopant drive-in process. For example, the substrate may be exposed to a heating or annealing step. According to some embodiments, the substrate may be introduced into a furnace for annealing, for example a quartz tube furnace. The inner diameter of the quartz tube may be about 290 millimeters to accommodate 156 millimeter pseudosquare substrates. The drive-in operation 215 may be used to accomplish several objectives at once. In an instance in which the dopant was deposited by ion implantation, the drive-in operation 215 may activate the implanted dopant atoms, such that the dopant atoms may substitute the substrate atoms thus changing the conductivity of the substrate. In some instances, the drive-in operation 215 may drive the dopant deeper, for example to a desired junction depth, into the substrate. As a result, an emitter, front surface field layer, and/or back surface field layer may be formed. Similarly, a p-n junction may be formed at the interface of the emitter and base layer of the substrate. In example embodiments, the drive-in operation 215 may repair damage to the crystalline lattice of the substrate caused by the dopant deposition.

Due to the dielectric layer formed in operation 205, diffusion of the dopant into the edges of the substrate may be reduced or eliminated in operation 215. In this regard, the dielectric layer may create a diffusion barrier along the sides of the solar cell. The dielectric layer may prevent or reduce the amount of dopant diffused into the sides of the solar cell without preventing diffusion into the front or back surfaces of the solar cell.

At operation 220, an antireflection layer may be formed on the front surface of the substrate. The antireflection layer may be formed by plasma enhanced chemical vapor deposition (PECVD). Alternatives to the PECVD process may include low pressure chemical vapor deposition (LPCVD), sputtering, and/or the like. The PECVD process may include heating the substrate to a temperature in the range of 300 to 500 degrees Celsius. Additionally, the PECVD process may include using silane and ammonia reactant gases. The thickness and index of refraction of the antireflection layer may be determined by parameters such as deposition time, plasma power, flow rate of reactant gasses, deposition pressure, and the like.

At operation 225, the material for the front contacts and front connections of the solar cell may be applied to the front surface of the antireflection layer. According to various embodiments, the front contacts and front connections may be screen-printed using a screen printer. The front contacts and front connections may be applied using a commercially available silver paste, for example, from Heraeus Corp, Dupont or the like. In some embodiments, the silver paste may contain frit to help penetrate the antireflection layer during firing of the contacts. The silver paste and firing conditions may be optimized specifically for forming contacts to emitters with low doping. The configuration and spacing of the front contacts and front connections may be defined by the contact pattern of the screen. In certain embodiments, the front contacts can be 50 to 150 micrometers in width and spaced apart by 1.5 to 2.5 millimeters. The paste for the front contacts and the front connections may be subsequently dried with a belt furnace. In other embodiments, the front contacts and front connections may be dried simultaneously with the back contact and back connections described in operation 130 below.

At operation 230, the material for the back contact and back connections may be applied to the back surface of the base layer. In certain embodiments, the back contact and back connections may be screen-printed on the back surface of the base layer. According to example embodiments, the back connections, such as solderable pads and bus bars, may be applied to the back surface of the base layer prior to the application of the back contact. The back connections may comprise silver or another solderable metal or material. The back contact may be printed to overlap the edges of the back connections while leaving a portion of the back connections exposed. In example embodiments, the back contact and back connections may be screen-printed across nearly the entire back surface of the base layer. In these embodiments, the aluminum paste of the back contacts may not be printed over a narrow border near the edges of the wafer approximately 1 mm wide. Alternatively, the back contacts and back connections may be printed across only a portion of the back surface of the substrate. The solar cell may optionally be placed on a belt furnace at a temperature of 150 to 350 degrees Celsius in air ambient for 30 to 300 seconds to dry the printed paste.

At operation 235, the substrate with the contacts and connections applied may be heated or co-fired in a belt furnace, such as an in-line belt furnace or the like. In the process of co-firing the structure, the front contacts and front connections may fire through the antireflection layer to form a physical connection with the substrate. In various embodiments, the front contacts may only make physical connection with the selective regions of a selective emitter or selective front surface field layer. To facilitate firing through the antireflection layer, the front contacts and front connections may contain frit, such as glass frit or the like. The glass frit in the paste used to form the front contacts and front connections may melt at a temperature near 500 degrees Celsius and dissolve the underlying antireflection layer.

During the co-firing at operation 235, the material of the back contact and back connections may form a physical contact with the back surface of the substrate. In certain embodiments, the firing of the back contact and back connections may occur above the aluminum-silicon eutectic temperature of 577 degrees Celsius. When the substrate cools following the co-firing, an aluminum-doped p⁺ silicon layer may form on the back surface of the substrate by liquid phase epitaxial re-growth. In these embodiments, the back contact, and in some instances the back connections, may be in electrical communication with the aluminum-doped p⁺ silicon layer. The temperature profile may feature a high heating rate, in the range of 20 degrees Celsius per second to 150 degrees Celsius per second, which promotes formation of a uniform interface between the textured back surface of the substrate and the aluminum-doped p⁺ silicon layer. Additionally, an aluminum back contact may also be formed on the back surface of the aluminum-doped p⁺ silicon layer during cooling.

The front and back connections may also become sintered or bonded to respective front and back contacts so that they are integrally connected and form good electrical connection to respective front and back sides of the solar cell. Connections may be adjoined via soldered wires to adjacent solar cells in a solar module and ultimately to a load to provide power thereto upon exposure of the solar cell to light.

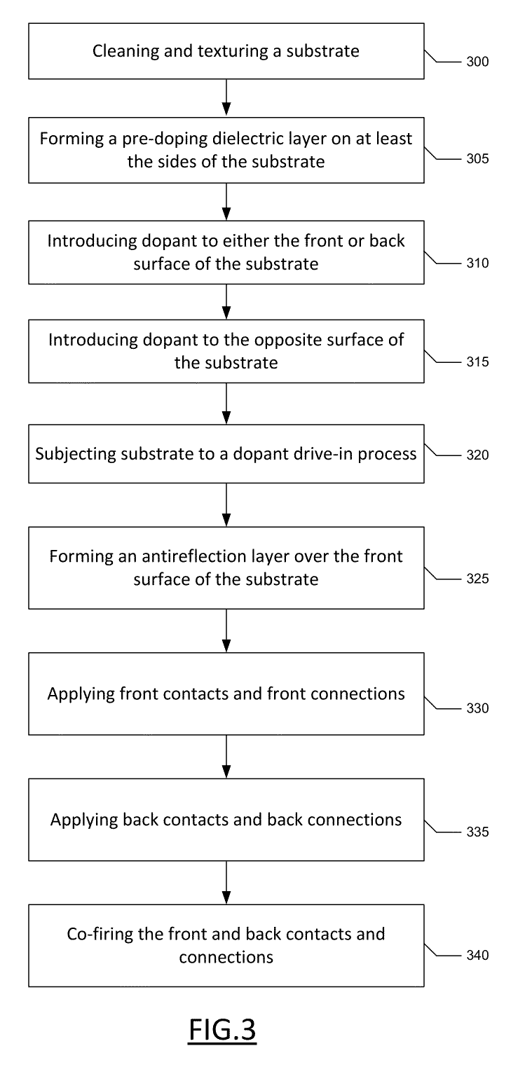

FIG. 3 illustrates a flowchart depicting an example method for forming a dielectric layer prior to a doping step according to an example embodiment of the present invention. Operations 300 to 305 may correspond to operations 200 to 205 of the example method depicted in FIG. 2. At operation 310, the process may proceed by introducing dopant to either the front or back surface of the substrate. At operation 315, dopant may be introduced into the opposite surface of the substrate. For example, if dopant is introduced into the front surface of the substrate at operation 310, operation 315 would comprise introducing dopant into the back surface of the substrate. In some embodiments, the conductivity type of the dopant introduced into the front surface may be opposite the conductivity type of the dopant introduced into the back surface. The method may continue at operation 320. Operations 320 to 340 may correspond to operations 215 to 235 of the example method depicted in FIG. 2.

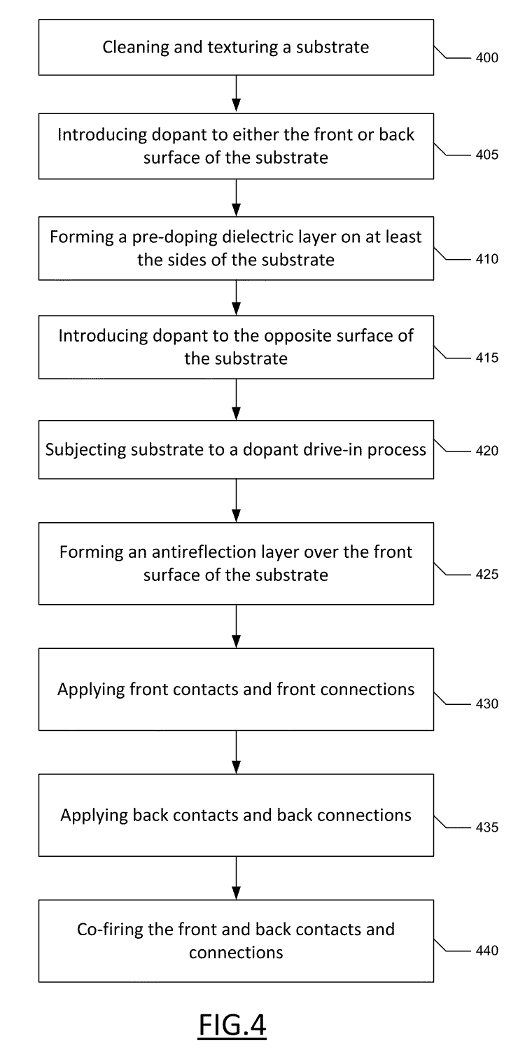

FIG. 4 illustrates a flowchart depicting an example method for forming a dielectric layer prior to a doping step according to an example embodiment of the present invention. Operation 400 may correspond to operation 200 of the example method depicted in FIG. 2. At operation 405, the process may proceed by introducing dopant to either the front or back surface of the substrate. At operation 410, a pre-doping dielectric layer may be formed on at least the sides of the substrate, as described with respect to operation 205 of the example method depicted in FIG. 2. At operation 415, dopant may be introduced into the opposite surface of the substrate doped in operation 405. For example, if dopant is introduced into the front surface of the substrate at operation 405, operation 415 would comprise introducing dopant into the back surface of the substrate. In some embodiments, the conductivity type of the dopant introduced into the front surface may be opposite the conductivity type of the dopant introduced into the back surface. The method may continue at operation 420. Operations 420 to 440 may correspond to operations 215 to 235 of the example method depicted in FIG. 2.

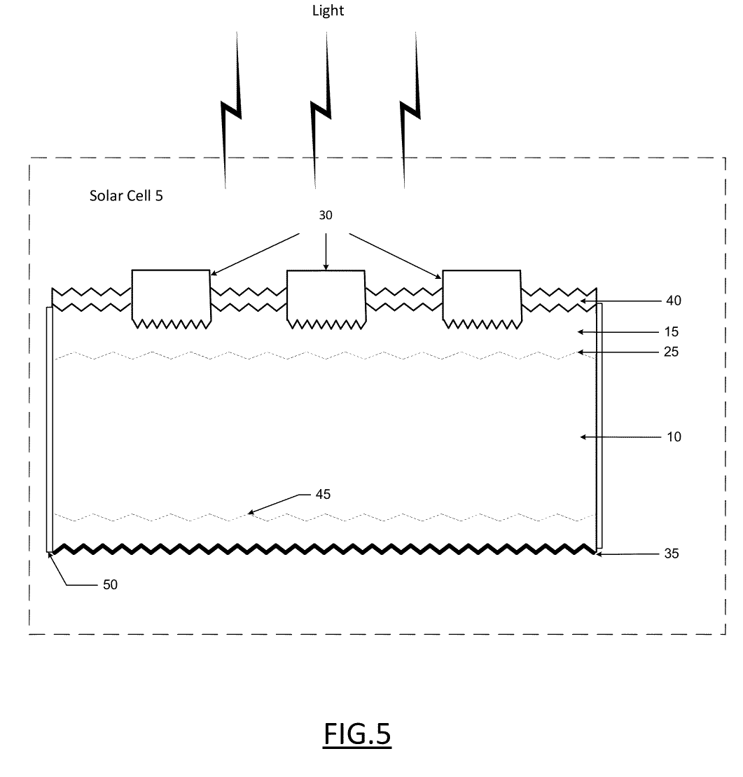

FIG. 5 illustrates an embodiment of a solar cell 5 that may benefit from embodiments of the present invention. The solar cell 5 may be formed of a semiconductor substrate. The substrate may be composed of silicon (Si), germanium (Ge) or silicon-germanium (SiGe) or other semiconductive material, or it may be a combination of such materials. Monocrystalline or multicrystalline, or possibly string ribbon, thin-film or other types of substrates, may be used. In the case of monocrystalline substrates, the semiconductor substrate may be grown from a melt using Float Zone (FZ) or Czochralski (Cz) techniques. The resulting mono-crystalline boule may then be sawn into a wafer which may be polished to form the substrate. For a substrate composed of silicon, germanium or silicon-germanium, the crystallographic orientation of the wafer surface may be (100) or (110), for example. The thickness of the substrate may be in a range from 50 to 500 μm, although savings of semiconductor material may be achieved relative to current standard substrates by using substrates with a thickness from 50 to less than 200 μm. Resistivity of the substrate may be in a range from 0.1 to 100 Ohm-cm, for example from 1 to 3 Ohm-cm.

The front and back surfaces of the substrate may be treated to remove saw damage and to texture the surfaces. For example, the surfaces may be treated to define pyramidal structures, such as by treating the surfaces with a solution of potassium hydroxide (KOH) and isopropyl alcohol (IPA) during an anisotropic etching process. The presence of the pyramidal structures on the front surface may increase the amount of light entering the solar cell 5 by reducing the amount of light that is lost by reflection from the front surface.

According to the embodiment of FIG. 5, the substrate may be doped with impurities of a first conductivity type. For example, in some embodiments, p-type impurities may be used to create a p-type base layer 10. The p-type base layer 10 may be doped with boron (B), gallium (Ga), indium (In), aluminum (Al), or possibly another Group III element to produce p-type conductivity. In other embodiments, the substrate may be doped with phosphorus (P), antimony (Sb), arsenic (As) or other Group V element to induce n-type conductivity, thereby forming an n-type base layer 10. In some embodiments, the dopant concentration may be in a range from 10¹⁴ to 10¹⁷ atoms per cubic centimeter (atoms/cm³) for a p-type base layer 10 or in a range from 10¹³ to 10¹⁷ atoms per cubic centimeter (atoms/cm³) for an n-type base layer 10.

The solar cell 5 of FIG. 5 may benefit from various embodiments of the present invention by comprising a dielectric layer 50 at least along the sides or edges of the substrate. The dielectric layer 50 may serve as a diffusion barrier for the edges of the solar cell 5 during the doping and diffusion of the emitter layer 15 and/or optional front or back surface field layer (not shown), which are described below. In this regard, the diffusion coefficient of the dopant, which is used to form the emitter layer 15 and/or optional front or back surface field layer, in the dielectric layer 50 may be lower than the diffusion coefficient of the dopant in silicon. Alternatively the segregation coefficient of the dopant may be such as to limit dopant diffusion into the silicon substrate. The dielectric layer 50 may have a thickness ranging from 0.5 to 150 nanometers.

The solar cell may further comprise an emitter layer 15. In the example solar cell 5 illustrated in FIG. 5, the emitter layer 15 may comprise a uniform emitter layer 15 formed into the front surface of the solar cell 5. In other embodiments, the emitter layer 15 may comprise a selective emitter layer 15 having one or more relatively lightly doped regions and one or more relatively heavily doped regions. The emitter layer 15 may be doped with impurities of a second conductivity type opposite that of the first conductivity type of the base layer 10. For example, in an instance in which the first conductivity type is p-type, the emitter layer 15 may comprise n-type dopant. In another example, in an instance in which the first conductivity type is n-type, the emitter layer 15 may comprise p-type dopant. A p-n junction 25 may be formed at the interface between the base layer 10 and the emitter layer 15. Because of their opposite conductivities, the base layer 10 and the emitter layer 15 create an electric field across the p-n junction 25 that separates free electrons and holes resulting from absorption of light photons and forces them to move in opposite directions to respective front and back contacts 30, 35. In some embodiments, the emitter layer 15 may be formed into the back surface of the solar cell 5 to create a back junction solar cell 5 (not shown).

In some embodiments, the solar cell 5 may optionally comprise a passivation layer (not shown) formed uniformly over the front surface to reduce recombination of charged carriers at the front surface of the emitter layer 15. The passivation layer, for example having a thickness of 0.5 nm to 50 nm, may be formed between the emitter layer 15 and the antireflection layer 40. The passivation layer may comprise silicon dioxide (SiO₂), silicon nitride (SiN_{X}), aluminum oxide (Al₂O₃), hafnium oxide (HfO₂), and/or combinations of these and/or other similar materials. In an instance in which the passivation layer comprises SiO₂, the passivation layer may be formed during operation 115 with the introduction of oxygen gas to the ambient.

In some embodiments, the solar cell 5 may optionally comprise a front surface field layer or a back surface field layer. The front or back surface field layer may be a uniform layer or a selective layer. The front or back surface field layer may be doped with impurities of the same conductivity type as that of the first conductivity type of the base layer 10.

The example solar cell 5 of FIG. 5 may further comprise an antireflection layer 40 formed over the front surface of the solar cell 5 to reduce reflection of the incident light and thus loss of solar energy. The antireflection layer 40 may have a refractive index less than that of the underlying substrate, which tends to cause light incident to the solar cell 5 to refract into the antireflection layer 40 and to the substrate where it can be converted to free charge carriers. For example, the antireflection layer 40 may have an index of refraction in the range of 1.9 to 2.4 when measured with an incident laser having a wavelength of 632.8 nm. The antireflection layer 40 may be composed of silicon nitride (SiN_{X}), silicon dioxide (SiO₂), aluminum oxide (Al₂O₃), hafnium oxide (HfO₂), titanium oxide (TiO₂), magnesium fluoride (Mg₂F), zinc oxide (ZnO), zinc sulfide (ZnS₂), or combinations of these and/or other similar materials. In some embodiments, the antireflection layer 40 comprises an amorphous nitride, such as amorphous silicon nitride (a-SiN_{X}). The antireflection layer 40 may have a thickness from 10 to 100 nanometers.

According to the embodiment of FIG. 5, the solar cell may comprise front and/or back contacts 30, 35 and/or connections. The front and back contacts 30, 35 and front and back connections may be formed of conductive materials such as silver (Ag), aluminum (Al), a combination of silver and aluminum, and/or the like. Generally, for silicon and other substrates, silver may be used to contact the surface of the substrate that is doped n-type; and aluminum, silver, or silver with aluminum additive may be used to contact the surface of the substrate that is doped p-type. Direct contact of metal to a semiconductor increases the recombination rate of electrons and holes, which can significantly lower solar cell efficiency. To decrease this effect and limit the proportion of metal covering the surface of the substrate, the front and back contacts 30, 35 and connections may be configured as point or line contacts (sometimes called “local contacts”). The spacing and arrangement of point or line contacts can be determined as described in U.S. Publication No. 2009/0025786 published Jan. 29, 2009, which is incorporated by reference as if set forth in full herein. The front and back connections may comprise solderable pads or bus bars to facilitate electrical connections to the front and back surfaces of the solar cell 5. According to example embodiments, the pattern of the front connections may be aligned with the pattern of the back connections.

In addition, for the front contacts 30 and front connections, silver may be selected because of its high electrical conductivity to limit shadowing effects that can lower solar cell efficiency. Various commercial silver pastes are available for this purpose, for example, from Heraeus Corp, Monocrystal, Ferro Corporation, Ruxing, Gigasolar, Dupont, or the like. However, silver is not transparent, so it may be desirable to limit the dimensions of the front contacts 30 and front connections to point or line contacts of limited area for this additional reason.

In an instance in which the emitter layer 15 comprises a selective emitter, the front contacts 30 may be aligned with the heavily doped regions of the selective emitter layer 15 to reduce the contact resistance. In certain embodiments, the width of the front contacts 30 may be less than the width of the heavily doped regions to ensure that the front contacts 30 are entirely within the heavily doped regions. The heavy doping in these selective regions also may increase the depth of the p-n junction 25 underneath, which may prevent shunting or firing through the p-n junction 25 by components of the metal paste used to form the front contacts 30. In accordance with certain embodiments, the antireflection layer 40 may be disposed on the front surface of the selective emitter layer 15 prior to forming the front contacts 30 and front connections. In this case, the front contacts 30 and front connections may physically penetrate the antireflection layer 40 to make contact with the underlying heavily doped regions of the selective emitter layer 15. The front contacts 30 and front connections may contain glass frit in addition to metal to facilitate their firing through the antireflection layer 40 to make contact with the selective emitter layer 15.

The back contact 35 and back connections of the example solar cell 5 of FIG. 5 may be formed on the back surface of the solar cell 5 using screen printed pastes. The paste used to form the back contact 35 may comprise an aluminum paste, such as those available from different paste vendors as Heraeus Corp, Monocrystal, Ferro Corporation, Ruxing, Gigasolar, Dupont, or the like. Additionally, the paste used to form the back connections may comprise an aluminum-silver paste, or the like that may allow solderable contacts to be formed. According to example embodiments, the back connections may be applied to the back surface of the solar cell 5 prior to the application of the back contact 35. In these embodiments, the back contact 35 may be printed to overlap the edges of the back connections while leaving a portion of the back connections exposed. In some embodiments, the back contact 35 and back connections may cover nearly the entire back surface of the solar cell 5, or in some instances, the back contact 35 and back connections may only cover a portion of the back surface of the solar cell 5. According to other embodiments, the back contact 35 may be printed across nearly the entire back surface of the solar cell 5 prior to applying the back connections. In these embodiments, the back connections may be applied over the back contact 35.

Due to the firing of the back contact 35, in some instances, an aluminum-doped p⁺ silicon layer 45 may be formed by liquid phase epitaxial regrowth at the interface of the back surface of the substrate and the back contact 35 of the solar cell 5 of FIG. 5. In these embodiments, the back contact 35 may make electrical contact with the back surface of the aluminum-doped p⁺ silicon layer 45. The back contact 35 may be composed of an aluminum-silicon eutectic composition. The back contact 35 may also serve as a reflective back layer for the solar cell 5. Having a reflective back layer provides a reflective surface to return incident light reaching the back to the substrate where it can generate free charge carriers. The thickness of the back contact 35 may be from 10 to 40 micrometers in thickness and provide adequate reflectivity.

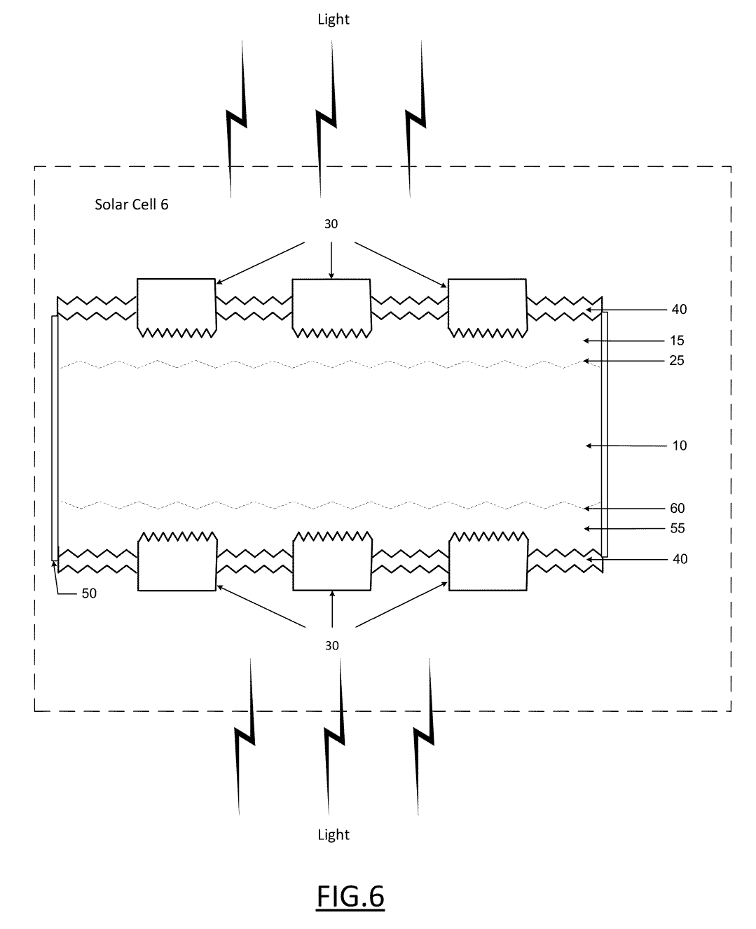

FIG. 6 illustrates an embodiment of a bifacial solar cell 6 that may benefit from embodiments of the present invention. The solar cell 6 may be formed of a semiconductor substrate. The substrate may be composed of silicon (Si), germanium (Ge) or silicon-germanium (SiGe) or other semiconductive material, or it may be a combination of such materials. Monocrystalline or multicrystalline, or possibly string ribbon, thin-film or other types of substrates, may be used. In the case of monocrystalline substrates, the semiconductor substrate may be grown from a melt using Float Zone (FZ) or Czochralski (Cz) techniques. The resulting mono-crystalline boule may then be sawn into a wafer which may be polished to form the substrate. For a substrate composed of silicon, germanium or silicon-germanium, the crystallographic orientation of the wafer surface may be (100) or (110), for example. The thickness of the substrate may be in a range from 50 to 500 μm, although savings of semiconductor material may be achieved relative to current standard substrates by using substrates with a thickness from 50 to less than 200 μm. Resistivity of the substrate may be in a range from 0.1 to 100 Ohm-cm, for example from 1 to 3 Ohm-cm.

The front and back surfaces of the substrate may be treated to remove saw damage and to texture the surfaces. For example, the surfaces may be treated to define pyramidal structures, such as by treating the surfaces with a solution of potassium hydroxide (KOH) and isopropyl alcohol (IPA) during an anisotropic etching process. The presence of the pyramidal structures on the surfaces may increase the amount of light entering the solar cell 6 by reducing the amount of light that is lost by reflection from the front and/or rear surface.

According to the embodiment of FIG. 6, the substrate may be doped with impurities of a first conductivity type. For example, in some embodiments, p-type impurities may be used to create a p-type base layer 10. The p-type base layer 10 may be doped with boron (B), gallium (Ga), indium (In), aluminum (Al), or possibly another Group III element to produce p-type conductivity. In other embodiments, the substrate may be doped with phosphorus (P), antimony (Sb), arsenic (As) or other Group V element to induce n-type conductivity, thereby forming an n-type base layer 10. In some embodiments, the dopant concentration may be in a range from 10¹⁴ to 10¹⁷ atoms per cubic centimeter (atoms/cm³) for a p-type base layer 10 or in a range from 10¹³ to 10¹⁷ atoms per cubic centimeter (atoms/cm³) for an n-type base layer 10.

The solar cell 6 of FIG. 6 may benefit from various embodiments of the present invention by comprising a dielectric layer 50 at least along the sides or edges of the substrate. The dielectric layer 50 may serve as a diffusion barrier for the edges of the solar cell 5 during the doping and diffusion of the emitter layer 15 and/or optional front or back surface field layer 55, which are described below. In this regard, the diffusion coefficient of the dopant, which is used to form the emitter layer 15 and/or optional front or back surface field layer 55, in the dielectric layer 50 may be lower than the diffusion coefficient of the dopant in silicon. Alternatively the segregation coefficient of the dopant may be such as to limit dopant diffusion into the silicon substrate. The dielectric layer 50 may have a thickness ranging from 0.5 to 150 nanometers.

The solar cell may further comprise an emitter layer 15. In the example solar cell 6 illustrated in FIG. 6, the emitter layer 15 may comprise a uniform emitter layer 15 formed into the front surface of the solar cell 6. In other embodiments, the emitter layer 15 may comprise a selective emitter layer 15 having one or more relatively lightly doped regions and one or more relatively heavily doped regions. The emitter layer 15 may be doped with impurities of a second conductivity type opposite that of the first conductivity type of the base layer 10. For example, in an instance in which the first conductivity type is p-type, the emitter layer 15 may comprise n-type dopant. In another example, in an instance in which the first conductivity type is n-type, the emitter layer 15 may comprise p-type dopant. A p-n junction 25 may be formed at the interface between the base layer 10 and the emitter layer 15. Because of their opposite conductivities, the base layer 10 and the emitter layer 15 create an electric field across the p-n junction 25 that separates free electrons and holes resulting from absorption of light photons and forces them to move in opposite directions to respective front and back contacts 30, 35. In some embodiments, the emitter layer 15 may be formed into the back surface of the solar cell 5 to create a back junction solar cell 6 (not shown).

In some embodiments, the solar cell 6 may optionally comprise a passivation layer (not shown) formed uniformly over the front and/or rear surface to reduce recombination of charged carriers at the surface of the emitter layer 15 opposite the substrate and/or the surface of the front or back surface field layer 55 opposite the substrate. The passivation layer, for example having a thickness of 0.5 nm to 50 nm, may be formed between the emitter layer 15 and/or front or back surface field layer 55 and the antireflection layer 40. The passivation layer may comprise silicon dioxide (SiO₂), silicon nitride (SiN_{X}), aluminum oxide (Al₂O₃), hafnium oxide (HfO₂), and/or combinations of these and/or other similar materials. In an instance in which the passivation layer comprises SiO₂, the passivation layer may be formed during operation 115 with the introduction of oxygen gas to the ambient.

In some embodiments, the solar cell 6 may optionally comprise a front surface field layer 55 or a back surface field layer 55. The solar cell 6 in FIG. 6 depicts a back surface field layer 55. The front or back surface field layer 55 may be a uniform layer or a selective layer. The front or back surface field layer 55 may be doped with impurities of the same conductivity type as that of the first conductivity type of the base layer 10.

The example solar cell 6 of FIG. 6 may further comprise an antireflection layer 40 formed over the front and/or rear surface of the solar cell 6 to reduce reflection of the incident light and thus loss of solar energy. The antireflection layer 40 may have a refractive index less than that of the underlying substrate, which tends to cause light incident to the solar cell 6 to refract into the antireflection layer 40 and to the substrate where it can be converted to free charge carriers. For example, the antireflection layer 40 may have an index of refraction in the range of 1.9 to 2.4 when measured with an incident laser having a wavelength of 632.8 nm. The antireflection layer 40 may be composed of silicon nitride (SiN_{X}), silicon dioxide (SiO₂), aluminum oxide (Al₂O₃), hafnium oxide (HfO₂), titanium oxide (TiO₂), magnesium fluoride (Mg₂F), zinc oxide (ZnO), zinc sulfide (ZnS₂), or combinations of these and/or other similar materials. In some embodiments, the antireflection layer 40 comprises an amorphous nitride, such as amorphous silicon nitride (a-SiN_{X}). The antireflection layer 40 may have a thickness from 10 to 100 nanometers. In an instance in which the antireflection layer 40 is formed on both the front and back surface of the solar cell 6, the antireflection layer 40 on the back surface need not be identical to the antireflection layer 40 on the front surface.

According to the embodiment of FIG. 6, the solar cell may comprise front and/or back contacts 30 and/or connections. The front and back contacts 30 and front and back connections may be formed of conductive materials such as silver (Ag), aluminum (Al), a combination of silver and aluminum, and/or the like. Generally, for silicon and other substrates, silver may be used to contact the surface of the substrate that is doped n-type; and aluminum, silver, or silver with aluminum additive may be used to contact the surface of the substrate that is doped p-type. Direct contact of metal to a semiconductor increases the recombination rate of electrons and holes, which can significantly lower solar cell efficiency. To decrease this effect and limit the proportion of metal covering the surface of the substrate, the front and back contacts 30 and connections may be configured as point or line contacts (sometimes called “local contacts”). The spacing and arrangement of point or line contacts can be determined as described in U.S. Publication No. 2009/0025786 published Jan. 29, 2009, which is incorporated by reference as if set forth in full herein. The front and back connections may comprise solderable pads or bus bars to facilitate electrical connections to the front and back surfaces of the solar cell 6. According to example embodiments, the pattern of the front connections may be aligned with the pattern of the back connections.

In addition, for the front and back contacts 30 and connections, silver may be selected because of its high electrical conductivity to limit shadowing effects that can lower solar cell efficiency. Various commercial silver pastes are available for this purpose, for example, from Heraeus Corp, Monocrystal, Ferro Corporation, Ruxing, Gigasolar, Dupont, or the like. However, silver is not transparent, so it may be desirable to limit the dimensions of the front and back contacts 30 and front connections to point or line contacts of limited area for this additional reason.

In an instance in which the emitter layer 15 comprises a selective emitter, the contacts 30 to the emitter layer 15 may be aligned with the heavily doped regions of the selective emitter layer 15 to reduce the contact resistance. In certain embodiments, the width of the contacts 30 to the emitter layer 15 may be less than the width of the heavily doped regions to ensure that the contacts 30 to the emitter layer 15 are entirely within the heavily doped regions. The heavy doping in these selective regions also may increase the depth of the p-n junction 25 underneath, which may prevent shunting or firing through the p-n junction 25 by components of the metal paste used to form the front contacts 30. In accordance with certain embodiments, the antireflection layer 40 may be disposed on the surface of the selective emitter layer 15 prior to forming the contacts 30 and connections to the emitter layer 15. In this case, the contacts 30 and connections to the emitter layer 15 may physically penetrate the antireflection layer 40 to make contact with the underlying heavily doped regions of the selective emitter layer 15. The contacts 30 and connections to the emitter layer 15 may contain glass frit in addition to metal to facilitate their firing through the antireflection layer 40 to make contact with the selective emitter layer 15.

The contacts 30 and connections to the surface field layer 55 of the example solar cell 6 of FIG. 6 may be formed on the surface of the solar cell 6 using screen printed pastes. The paste used to form the contacts 30 and connections to the surface field layer 55 may comprise a silver paste available from different paste vendors such as Heraeus Corp, Monocrystal, Ferro Corporation, Ruxing, Gigasolar, Dupont, or the like. In an instance in which the surface field layer 55 comprises a selective layer, the contacts 30 to the surface field layer 55 may be aligned with the heavily doped regions of the selective surface field layer 55 to reduce the contact resistance. In certain embodiments, the width of the contacts 30 to the surface field layer 55 may be less than the width of the heavily doped regions to ensure that the contacts 30 to the surface field layer 55 are entirely within the heavily doped regions. The heavy doping in these selective regions also may increase the depth of the surface field 60 underneath, which may prevent firing through the surface field 60 by components of the metal paste used to form the contacts 30 to the surface field layer 55. In accordance with certain embodiments, the antireflection layer 40 may be disposed on the surface of the selective surface field layer 55 prior to forming the contacts 30 and connections to the surface field layer 55. In this case, the contacts 30 and connections to the surface field layer 55 may physically penetrate the antireflection layer 40 to make contact with the underlying heavily doped regions of the selective surface field layer 55. The contacts 30 and connections to the surface field layer 55 may contain glass frit in addition to metal to facilitate their firing through the antireflection layer 40 to make contact with the selective surface field layer 55.

According to various embodiments, and as described above, a solar cell may be formed comprising a pre-doping dielectric layer. Many advantages may be realized by forming the pre-doping dielectric layer as described herein. For example, according to various advantageous embodiments, the growth or deposition of a dielectric layer on at least the edges of the substrate may reduce or prevent diffusion of dopant into the sides of the solar cell, thus impeding the shunt path and increasing the shunt resistance without the need for junction isolation. In these advantageous embodiments, the presence of the dielectric layer may otherwise have no detrimental effect on the performance of the solar cell, such as by decreasing the efficiency and/or fill factor of the solar cell. As a result, various advantageous embodiments may reduce the number of manufactured cells classified as shunts, namely having a shunt across the p-n junction, which have little or no commercial value. In some advantageous embodiments, the pre-doping dielectric layer may enable more reliable 72-cell (or higher cell count) module performance. In this regard, embodiments of the present invention may reduce the number of bypass diodes required for reliable module performance, for example from four to three bypass diodes. Additionally, various advantageous embodiments of the present invention may enable solar cell configurations that have previously failed to pass hot spot testing due to high reverse bias leakage current to pass hot spot testing by significantly reducing the reverse bias leakage current. Some advantageous embodiments may be applicable to solar cells where opposite sides of the solar cells are doped with dopants of opposing conductivities (e.g., bifacial cells). These solar cells may benefit from the process flows described in other embodiments, such as those illustrated in FIGS. 2 through 4. In these advantageous embodiments, the dielectric deposition step may be completed as an intermediate step between doping steps or prior to both doping steps.

Many modifications and other embodiments of the inventions set forth herein will come to mind to one skilled in the art to which these inventions pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of steps, elements, and/or materials than those explicitly described above are also contemplated as may be set forth in some of the appended claims. Accordingly, the specification and drawings are to be regarded in an illustrative rather than restrictive sense. Although specific terms are employed herein, they are used in a generic and descriptive sense only and not for purposes of limitation.

What is claimed is:

1. A method for manufacturing a solar cell comprising:
forming a dielectric layer on at least one or more edges of a substrate, and then;
introducing dopant to at least one surface of the substrate; and
subjecting the substrate to a heating process to at least drive the dopant to a predefined depth, thereby forming at least one of an emitter layer and a surface field layer;
wherein the dielectric layer is not removed during a subsequent manufacturing process.

2. The method of claim 1, wherein introducing dopant to at least one surface of the substrate further comprises:
introducing dopant to a first surface of the substrate such that subjecting the substrate to the heating process thereby forms an emitter layer proximate the first surface.

3. The method of claim 2, wherein introducing dopant to at least one surface of the substrate further comprises:
introducing dopant to a second surface of the substrate opposite the first surface such that subjecting the substrate to the heating process thereby forms a surface field layer proximate the second surface.

4. The method of claim 3, wherein the dopant introduced to the first surface is of a first conductivity type, and the dopant introduced to the second surface is of a second conductivity type opposite the first conductivity type.

5. The method of claim 1, wherein forming a dielectric layer on at least one or more edges of a substrate further comprises:
forming a dielectric layer on at least one surface of the substrate.

6. The method of claim 1, further comprising:
forming an antireflection layer over at least one surface of the substrate.

7. The method of claim 1, wherein forming a dielectric layer and introducing dopant further comprises:
introducing dopant to a first surface of the substrate, and then;
forming a dielectric layer on at least one or more edges of a substrate, and then;
introducing dopant to a second surface of the substrate opposite the first surface.

8. The method of claim 1, further comprising:
screen-printing one or more first contacts over a first surface of the substrate; and
screen-printing one or more second contacts over a second surface of the substrate opposite the first surface.

9. The method of claim 8, further comprising:
co-firing the one or more first and second contacts.

10. The method of claim 1, wherein introducing dopant to at least one surface of the substrate further comprises:
introducing dopant to at least one surface of the substrate by ion implantation.

11. A solar cell manufactured by the steps of:
forming a dielectric layer on at least one or more edges of a substrate, and then;
introducing dopant to at least one surface of the substrate; and
subjecting the substrate to a heating process to at least drive the dopant to a predefined depth, thereby forming at least one of an emitter layer and a surface field layer;
wherein the dielectric layer is not removed during a subsequent manufacturing process.

12. The solar cell of claim 11, wherein introducing dopant to at least one surface of the substrate further comprises:
introducing dopant to a first surface of the substrate such that subjecting the substrate to the heating process thereby forms an emitter layer proximate the first surface.

13. The solar cell of claim 12, wherein introducing dopant to at least one surface of the substrate further comprises:
introducing dopant to a second surface of the substrate opposite the first surface such that subjecting the substrate to the heating process thereby forms a surface field layer proximate the second surface.

14. The solar cell of claim 13, wherein the dopant introduced to the first surface is of a first conductivity type, and the dopant introduced to the second surface is of a second conductivity type opposite the first conductivity type.

15. The solar cell of claim 11, wherein forming a dielectric layer on at least one or more edges of a substrate further comprises:
forming a dielectric layer on at least one surface of the substrate.

16. The solar cell of claim 11, further manufactured by the steps of:
forming an antireflection layer over at least one surface of the substrate.

17. The solar cell of claim 11, further manufactured by the steps of:
introducing dopant to a first surface of the substrate, and then;
forming a dielectric layer on at least one or more edges of a substrate, and then;
introducing dopant to a second surface of the substrate opposite the first surface.

18. The solar cell of claim 11, further manufactured by the steps of:
screen-printing one or more first contacts over a first surface of the substrate;
screen-printing one or more second contacts over a second surface of the substrate opposite the first surface; and
co-firing the one or more first and second contacts.

19. The solar cell of claim 11, wherein introducing dopant to at least one surface of the substrate further comprises:
introducing dopant to at least one surface of the substrate by ion implantation.

20. A solar module comprising one or more solar cells manufactured by the steps of:
forming a dielectric layer on at least one or more edges of a substrate, and then;
introducing dopant to at least one surface of the substrate; and
subjecting the substrate to a heating process to at least drive the dopant to a predefined depth, thereby forming at least one of an emitter layer and a surface field layer;
wherein the dielectric layer is not removed during a subsequent manufacturing process.
